(19) United States
(12) Patent Application Publication
(10) Pub. No.: US 2024/0096935 A1
(43) Pub. Date: Mar. 21, 2024

(54) SEMICONDUCTOR ELEMENT WITH SHIELDING

(71) Applicant: Robert Bosch GmbH, Stuttgart (DE)

(72) Inventors: Christian Huber, Ludwigsburg (DE); Jens Baringhaus, Sindelfingen (DE); Kevin Dannecker, Reutlingen (DE); Muhammad Alshahed, Stuttgart (DE)

(21) Appl. No.: 18/466,223

(22) Filed: Sep. 13, 2023

(30) Foreign Application Priority Data
Sep. 19, 2022 (DE) 10 2022 209 801.3

(51) Int. Cl. H01L 29/06; H01L 21/265; H01L 21/28; H01L 29/20; H01L 29/423; H01L 29/66; H01L 29/778

(52) U.S. Cl. CPC H01L 29/063; H01L 21/26546; H01L 21/28264; H01L 29/2003; H01L 29/4236; H01L 29/66462; H01L 29/7787

(57) ABSTRACT

A semiconductor component that is designed as a trench MISFET. The semiconductor component includes a substrate made of gallium nitride (GaN), a drift layer situated thereon, a barrier layer, and a source region situated thereabove. The source region includes a gate trench that extends from the source region into the underlying barrier layer.

### FIELD

The present invention relates to a semiconductor component in a vertical construction, which is designed as a trench MISFET based on gallium nitride and which includes a gate trench, with p-implant-free shielding, that is formed in a barrier layer. Moreover, the present invention relates to a method for manufacturing a trench MISFET based on gallium nitride.

### BACKGROUND INFORMATION

Gallium nitride is a preferred material system or substrate material for semiconductor components, since these components have a low electrical resistance in the conducting direction or in a conducting mode (on-resistance), at the same time with higher breakdown voltages or breakdown field strengths in the blocking state of the semiconductor component than comparable components based on silicon or silicon carbide. Furthermore, with regard to the design of semiconductor components, in addition to a conventional, essentially horizontal arrangement of the electrodes, a vertical arrangement of at least two electrodes of a component, one above the other, is a prevalent configuration or design alternative for allowing provision of appropriately miniaturized semiconductor components.

One conventional possible design is the so-called trench MISFET, in which a vertical arrangement, one above the other, of a strongly n-doped substrate, a weakly n-doped drift layer, and p-doped regions, in which an inversion channel forms at the boundary surface of a gate dielectric that is situated in a trench filled with the gate metal.

In order to protect the gate dielectric in the trench base from the high field strengths that occur in the blocked case, which otherwise would destroy the component, p-doped regions which are situated more deeply in comparison to the trench base are provided at the transition between the drift layer and the p-doped regions, and which in the blocked case result in more rapid propagation of the space charge region between the p region and the n region and create the space charge region deeper in the semiconductor, as the result of which the field strength load in the gate dielectric is reduced.

The creation of such p-doped regions for shielding purposes is in principle possible with the aid of epitaxy or ion implantation. In contrast to the p implantation, epitaxially grown p regions are implementable in a much more reliable manner; however, to create the deep shielding structures, here as well high-energy ion implantations are required. The implanted species must be effectively incorporated into the semiconductor crystal and activated, which for gallium nitride-based semiconductors, however, is problematic.

In addition, due to the high ionization energy of the magnesium used as dopant, p regions may be implemented with the aid of implantation only to a limited extent, in particular since the p-doping for the desired shielding structures is to be high, and at the same time must be introduced deep into the semiconductor. It is also disadvantageous that the high ionization energy results in a temperature dependency of the hole concentration in the p region, and thus in a temperature dependency of the blocking capability.

### SUMMARY

A gallium nitride-based semiconductor component, designed as a trench MISFET, according to the present invention, may have the advantage that due to the n implantation in the area below the gate trench, effective shielding is provided, while avoiding the costly and unreliable magnesium high-energy implantation from the related art. Much lower implantation energies are required, thus enabling a reduction in the manufacturing costs and better control of the geometry of the resulting implantation profile. In particular, by dispensing with the deeper p regions of the cell pitch, provided in addition to the gate trench in the related art, the minimum distance between two repeating features in the cell field of the transistor may be reduced.

For a semiconductor component according to an example embodiment of the present invention designed as a trench MISFET, it is provided that this semiconductor component includes a substrate made of gallium nitride (GaN), a drift layer situated thereon, a barrier layer or barrier region, and a source region situated thereabove, the source region including a gate trench that extends from the source region into the underlying barrier layer. According to the present invention, a trench base of the gate trench is situated in the barrier layer, and provided below the trench base and the gate trench is an n-doped region, at least partially laterally enclosing same, that is created with the aid of implantation and that extends into the drift layer.

Advantageous refinements and example embodiments of the semiconductor component according to the present invention are disclosed herein. The present invention is described below in particular for a unit cell of a transistor.

Due to the formation of the implanted n-doped region situated below and partially to the side, the end of the inversion channel ends in the n-doped region, thus ensuring a current flow from the source region into the drift layer. According to an example embodiment of the present invention, it is particularly preferably provided that the implanted n-doped region laterally encloses a lower section of the gate trench up to a predefined height, which in a side view of the semiconductor component is above a gate oxide layer which is formed in the trench base, and which thus laterally overhangs it.

According to an example embodiment of the present invention, the n-doping of the implanted area is advantageously selected to be so high that it overcompensates for a p-doping of the epitaxial barrier layer. It is also advantageous that the n-doped region is preferably formed at a boundary region between the barrier layer and the drift layer, the n-doped region having a larger width extension than the gate trench. A width extension of the n-doped region, i.e., the maximum width, may be 5% to 50%, more preferably 10% to 40%, of the width extension of the gate trench. In addition, the n-doped region may extend into the drift layer up to a predefined depth, which is 15% to 50%, more preferably 20% to 40%, of the width extension of the n-doped region. By the selection of the width and depth of the implanted n region, the effectiveness of the shielding may be matched to the electrical resistance in the switched-on state.

The barrier layer advantageously has a thicker design than the conventional epitaxial stack from the related art. According to an example embodiment of the present invention, it may particularly advantageously be provided that the barrier layer includes an area, neighboring the drift layer, with increased p-doping compared to the remaining barrier layer.

The drift layer is advantageously free of p-doped regions, in particular deeper p-doped regions, situated therein. According to an example embodiment the present invention, these are not necessary in order to achieve the desired shielding. In this way, the cell pitch of the transistor may be reduced and the number of MOS channels per surface area may be increased.

A first method according to the present invention relates to a method for manufacturing a semiconductor component, in particular a trench MISFET, that is designed according to one of the above-described specific embodiments. According to an example embodiment of the present invention, the method includes at least the following method steps: formation of a drift layer on a gallium nitride substrate; formation of a p-doped barrier layer, the barrier layer optionally including a layer, neighboring the drift layer, with increased p-doping compared to the remaining barrier layer; formation of an n-doped source region situated thereabove; application of a gate trench in a surface of the n-doped layer in such a way that a trench base is situated in a lower area of the barrier layer or of the layer optionally formed therein with increased p-doping; implantation, in particular silicon implantation, of an n-doped region below the trench base in such a way that the n-doped region is situated below the trench base and at least partially laterally encloses the gate trench, and extends into the drift layer.

By use of this method, which with regard to the layer growth, the layer structuring, and the possible influencing and processing of formed, in particular grown, layers, reverts to basically conventional methods and techniques of semiconductor technology, a trench MISFET that allows a desired shielding, in particular of the gate dielectric in the trench base, from high field strengths in the blocked case of the transistor may be provided in a particularly advantageous manner. According to the method described above, an implantation, in particular a flat implantation, takes place in the previously applied gate trench. Due to the flat implantation into the gate trench, very low implantation energies are required, so that the manufacturing costs are kept extremely low, and the geometry of a desired implantation profile of the n-doped region may be optimally controlled.

In one alternative specific embodiment, the method according to the present invention relates to a method for manufacturing a semiconductor component, in particular a trench MISFET, that is designed according to one of the preceding specific embodiments, the method according to the present invention including at least the following method steps: formation of a drift layer on a gallium nitride substrate; formation of a p-doped barrier layer, the barrier layer optionally including a layer, neighboring the drift layer, with increased p-doping compared to the remaining barrier layer; formation of an n-doped source region thereabove; implantation, in particular silicon implantation, of an n-doped region into a boundary region between the barrier layer and the drift layer in such a way that the implanted area extends at least partially into the drift layer and has a width extension that is selected to be larger than a gate trench to be applied; application of a gate trench in a surface of the n-doped layer in such a way that a trench base and at least one lower section of the gate trench are situated within the implanted area.

In this alternative method according to the present invention, a deep implantation of the n-doped region, starting from the surface of the source region, now initially takes place before the gate trench is formed or applied in the source region.

The flat or deep silicon implantation according to the present invention according to one of the example methods described above advantageously takes place in such a way that an overimplantation of the already present p-doping of the barrier layer occurs. The resulting implanted area accordingly has such high n-doping that the p-doping of the epitaxial barrier layer is overcompensated for. By selecting a suitable width and depth of the implanted n region, in addition the effectiveness of the shielding may be matched with the electrical resistance in the switched-on state.

It is also advantageous that the above-mentioned alternative methods of the present invention include the further step of implementing a conventional gate structure, at the semiconductor component. The above-mentioned alternative methods particularly advantageously include the further step of forming a gate oxide layer in the applied gate trench in such a way that in the side view, the gate oxide layer in the trench base is situated within a vertical extension of the implanted n-doped region at the trench or to the side of the trench.

Further advantages, features, and particulars of the present invention result from the following description of preferred specific embodiments of the present invention and with reference to the figures.

### BRIEF DESCRIPTION OF THE DRAWINGS

FIG. 1 shows a section through a layer structure of a trench MISFET according to the related art.

FIGS. 2A through 2C each show a section through a layer structure in the method for manufacturing a trench MISFET according to the present invention, according to a first specific embodiment.

FIGS. 3A through 3C each show a section through a layer structure in the method for manufacturing a trench MISFET according to the present invention, according to a second specific embodiment.

### DETAILED DESCRIPTION OF EXAMPLE EMBODIMENTS

Identical elements or elements having the same function are provided with the same reference numerals in the figures.

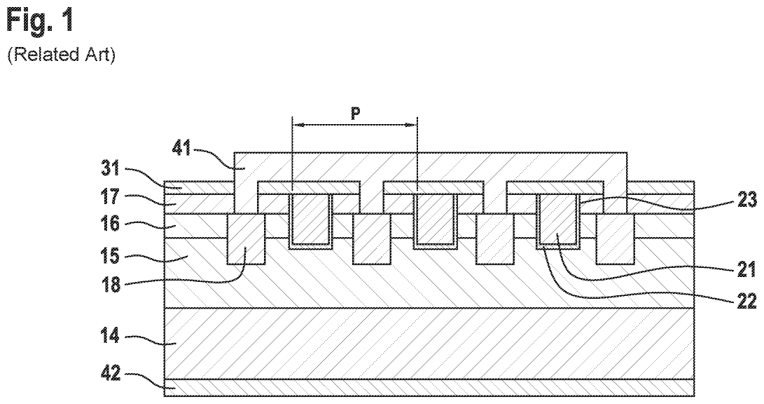

FIG. 1 shows the basic design of a conventional trench MISFET 100 from the related art, for three unit cells. The generic transistor includes a strongly n-doped GaN substrate 14, a weakly n-doped drift layer 15 situated thereabove, p-doped GaN regions 16 situated thereabove as a barrier layer, and a source region 17 situated thereabove with strongly n-doped regions, including a trench structure or gate trench 23 extending therefrom into underlying barrier layer 16 and drift layer 15. The inversion channel forms at the boundary surface for a gate dielectric 22, which is situated in gate trench 23 filled with gate metal 21.

A source electrode 41 contacts p regions 16, 18 as well as n regions 17, and is separated from the gate metal via an insulating layer 31. Drain electrode 42 is situated on the bottom side of GaN substrate 14. Without application of a gate voltage, p-doped GaN region 16 is blocking; no current flow takes place, and the transistor blocks up to its breakdown voltage. When a positive gate voltage is applied to gate metal 21, a conductive n channel forms below gate dielectric 22 within p-doped GaN region 16, as the result of which current flows from the drain to the source.

For purposes of shielding trench base 23a against the high field strengths that occur in the blocked case, the generic transistor additionally includes p regions 18 which are situated more deeply compared to the trench base, and which have been created by deep implantation, in particular for components made of silicon or silicon carbide.

One design variable is so-called pitch P, which represents the minimum distance between two repeating features in the cell field of transistor 100. The smaller the pitch, the more inversion channels that may be connected in parallel per unit area, as the result of which the electrical resistance in the switched-on state is reduced and the component power is increased.

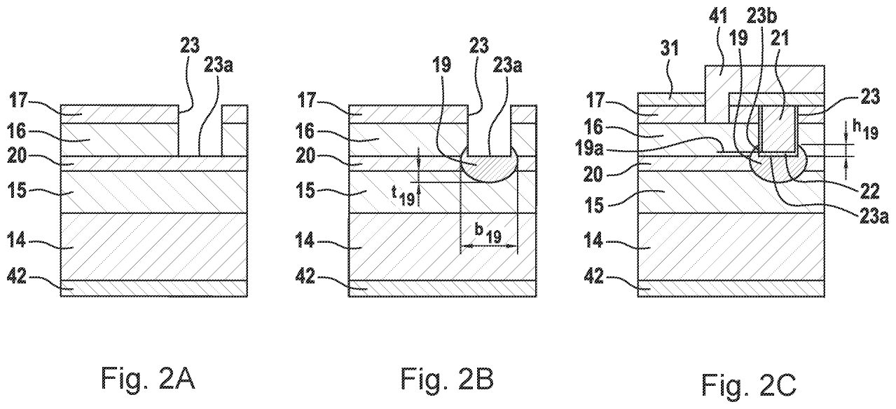

FIGS. 2A through 2C show, with reference to sections through the particular layer structure, one preferred specific embodiment of the manufacturing method according to the present invention and of semiconductor component 100 according to the present invention, in each case for a unit cell.

The basic design of the epitaxial stack corresponds to the design according to FIG. 1, p-doped layer 16 now having a thicker design. In a lower area, this p-doped layer may optionally have a layer 20 with increased p-doping compared to remaining layer 16. The depth of p regions 16, 20 may correspond to the depth of p regions 18 provided in the related art for shielding purposes (cf. FIG. 1).

As shown in FIG. 2A, the individual layers of the epitaxial stack, i.e., a drift layer 15, a p-doped barrier layer 16, with an optionally provided layer 20 therein with increased p-doping, neighboring drift layer 15, and an n-doped source region 17 situated thereabove, are formed on a GaN substrate 14 in a conventional manner.

In addition, the application of a gate trench 23 in a surface of n-doped layer 17 takes place in such a way that a trench base 23a is situated in a lower area of barrier layer 16, or of layer optionally formed therein with increased p-doping. Thus, in contrast to the related art, gate trench 23 does not reach into drift layer 15, and instead ends in p-doped layer 16 or 20.

As shown in FIG. 2B, a flat implantation, in particular a silicon implantation, of an n-doped region 19 below trench base 23a subsequently takes place in order to provide the necessary electrical connection between source region 17 and drift layer 15. This implantation takes place in such a way that n-doped region 19 is situated below trench base 23a, and gate trench 23 is at least partially enclosed at the side and reaches into drift layer 15. n-doped region 19 is so highly n-doped that the p-doping of epitaxial layer 16 and 20 is overcompensated for. In addition, implanted n-doped region 19 in each case extends to the side of gate trench 23 up to a height h19, which is higher than a gate dielectric layer 22 that is to be provided in trench base 23a. In particular, n-doped region 19 reaches to beyond mark 19a (cf. FIG. 2C). In addition, by selecting width b19 and depth t19 of implanted n region 19 in drift layer 15, the effectiveness of the shielding may be matched with the electrical resistance in the switched-on state.

As illustrated in FIG. 2C, a conventional gate structure, in particular a dielectric layer 22 situated in trench 23 and a gate metal 21 situated in trench 23, is/are subsequently formed at the semiconductor component, and an insulating layer 31 and a source electrode 41 are provided.

In contrast to p-doped region 16 in the generic transistor design in FIG. 1, epitaxially grown p region 16, 20 in the semiconductor component according to the present invention now reaches to below trench 23, and thus replaces more deeply situated p region 18 in FIG. 1. A great reduction of cell pitch P is achieved by dispensing with deeper p regions 18 from the related art.

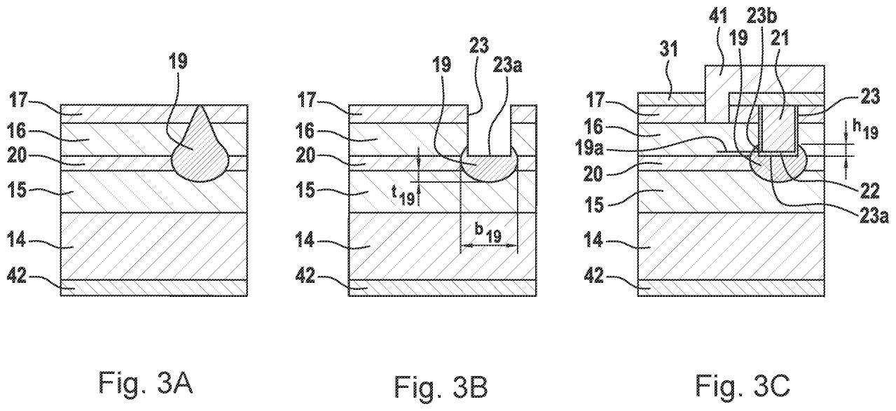

FIGS. 3A through 3C show, with reference to sections through the particular layer structure, a further preferred specific embodiment of the manufacturing method according to the present invention and semiconductor component 100 according to the present invention, in each case for a unit cell.

In accordance with the specific embodiment according to FIGS. 2A through 2C, formation of the particular layers of the epitaxial stack on a GaN substrate 14 initially takes place, the basic arrangement of the epitaxial layers corresponding to the arrangement according to FIGS. 2A through 2C. However, in a departure from the preceding exemplary embodiment, prior to the formation of gate trench 23 an implantation of an n-doped region 19 starting from source region 17 is carried out, as illustrated in FIG. 3A. In particular, a deep implantation of n-doped region 19 into a boundary region between barrier layer 16, 20 and drift layer 15 takes place in such a way that the implanted area at least partially extends into drift layer 15 and has a width extension b19 that is selected to be larger than gate trench 23 to be subsequently applied. Implanted region 19 is thus so highly doped that the p-doping of epitaxial layer 16 and is overcompensated for.

As illustrated in FIG. 3B, the application of a gate trench 23 in a surface of n-doped layer 17 subsequently takes place in such a way that trench base 23a is situated in implanted n-doped region 19, and the trench thus does not reach into drift layer 15. In particular, trench 23 is applied in such a way that a trench base 23a and at least one lower section 23b of gate trench 23 are situated within implanted area 19.

As shown in FIG. 3C, a conventional gate structure is subsequently formed at semiconductor component 100. This encompasses at least the forming of a gate oxide layer 22 in applied gate trench 23 in such a way that in the side view, the gate oxide layer in trench base 23a is situated within a vertical extension h19 of implanted n-doped region 19 laterally to gate trench 23. As shown in FIG. 3C, gate trench 23 and the gate structure are designed in such a way that gate dielectric 22 is situated in trench base 23a at the same height or deeper (cf. mark 19a) than n-doped region 19, which laterally abuts lower section 23b of the trench up to a height h19.

1-11. (canceled)

12. A semiconductor component configured as a trench metal insulator semiconductor field effect transistor (MISFET), comprising:
a substrate made of gallium nitride (GaN);
a drift layer situated on the substrate;
a barrier layer; and
a source region situated above the barrier layer, the source region including a gate trench that extends from the source region into the barrier layer, wherein a trench base of the gate trench is situated in the barrier layer, and provided below the trench base and the gate trench is an n-doped region, the n-doped region at least partially laterally enclosing the trench base, the n-doped region is created using implantation and extends into the drift layer.

13. The semiconductor component as recited in claim 12, wherein the n-doped region laterally encloses a lower section of the gate trench up to a predefined height that is above a gate oxide layer that is formed in the trench base.

14. The semiconductor component as recited in claim 12, wherein the n-doped region is formed at a boundary region between the barrier layer and the drift layer, and the n-doped region has a larger width extension than the gate trench.

15. The semiconductor component as recited in claim 12, wherein the barrier layer includes an area, neighboring the drift layer, with increased p-doping compared to a remaining portion of the barrier layer.

16. The semiconductor component as recited in claim 12, wherein an n-doping of the n-doped region is selected to be so high that it overcompensates for a p-doping of the barrier layer.

17. The semiconductor component as recited in claim 12, wherein the drift layer, except for n-doped regions that extend into the drift layer, is free of deeper p-doped regions, situated therein.

18. The semiconductor component as recited in claim 12, wherein the n-doped region is created using silicon implantation.

19. A method for manufacturing a semiconductor component configured as a trench metal insulator semiconductor field effect transistor (MISFET), the method comprising the following steps:
forming a drift layer on a gallium nitride substrate;
forming a p-doped barrier layer;
forming an n-doped source region situated above the p-doped barrier layer;
applying a gate trench in a surface of the n-doped source region in such a way that a trench base is situated in a lower area of the barrier layer;
silicon implantation of an n-doped region below the trench base in such a way that the n-doped region is situated below the trench base and at least partially laterally encloses the gate trench, and extends into the drift layer.

20. The method as recited in claim 19, wherein the barrier layer includes a layer, neighboring the drift layer, with increased p-doping compared to a remaining portion of the barrier layer.

21. A method for manufacturing a semiconductor component configured as a trench metal insulator semiconductor field effect transistor (MISFET), the method comprising the following steps:
forming a drift layer on a gallium nitride substrate;
forming a p-doped barrier layer;
forming an n-doped source region situated above the barrier layer;
silicon implantation of an n-doped region into a boundary region between the barrier layer and the drift layer in such a way that an implanted area extends at least partially into the drift layer and has a width extension that is selected to be larger than a gate trench to be applied; and
applying the gate trench in a surface of the n-doped source region in such a way that a trench base and at least one lower section of the gate trench are situated within the implanted n-doped region.

22. The method as recited in claim 21, wherein the barrier layer includes a layer, neighboring the drift layer, with increased p-doping compared to a remaining portion of the barrier layer.

23. The method as recited in claim 21, the method further including:
forming a gate oxide layer in the applied gate trench in such a way that in a side view, the gate oxide layer in the trench base is situated within a vertical extension of the implanted n-doped region at the gate trench.

24. The method as recited in claim 19, wherein the silicon implantation takes place in such a way that the implanted n-doped region has an n-doping so high that it overcompensates for a p-doping of the barrier layer.
